(19) United States
(12) Patent Application Publication
(10) Pub. No.: US 2026/0255502 A1
(43) Pub. Date: Aug. 27, 2026

(54) VIA FORMATION USING IMPRINT LITHOGRAPHY AND RETARGETING VIAS FORMED BY SAME

(71) Applicant: Taiwan Semiconductor Manufacturing Company, LTD., Hsinchu (TW)

(72) Inventors: Hsin-Yuan Lee, Hsinchu (TW); Yu-Luen Deng, Tainan (TW)

(21) Appl. No.: 19/230,300

(22) Filed: Jun. 6, 2025

Related U.S. Application Data
(60) Provisional application No. 63/762,821, filed on Feb. 25, 2025.

(51) Int. Cl. H05K 3/40; H05K 1/11; H05K 3/06

(52) U.S. Cl. CPC H05K 3/4038; H05K 1/115; H05K 3/061; H05K 2201/09827; H05K 2201/09836

(57) ABSTRACT

A resist layer is formed over the dielectric layer. A pattern of via openings is imprinted in the resist layer, for example using nano imprint lithography. After the imprinting, the pattern of via openings imprinted in the resist layer is transferred to the dielectric layer by anisotropic etching to form via openings in the dielectric layer. The anisotropic etching has low etching selectivity between the resist layer and the dielectric layer. The via openings in the dielectric layer are filled with an electrically conductive material to form vias in the dielectric layer. A center line of at least one retargeting via of the vias is not parallel with a center line of at least one other via of the vias.

This application claims the benefit of U.S. Provisional Application No. 63/762,821 filed Feb. 25, 2025. U.S. Provisional Application No. 63/762,821 filed Feb. 25, 2025 is incorporated herein by reference in its entirety.

### BACKGROUND

The following relates to the integrated circuit (IC) arts, three-dimensional integrated circuit (3DIC) arts, IC fabrication arts, back end-of-line (BEOL) processing arts, semiconductor fabrication arts, and related arts.

In the BEOL processing phase of IC fabrication, a metallization stack is formed to electrically interconnect electronic devices of the IC and to provide bonding pads or the like for external electrical connection of the IC. The metallization stack includes patterned metallization layers interconnected by vias, with the metallization layers and vias disposed or embedded in intermetal dielectric (IMD) material, also referred to in the art by similar nomenclatures such as interlayer dielectric (ILD) material.

In 3DIC design, metallization stacks can be formed on two (or more) processed wafers, with the metallization stacks having aligned surface bonding pads enabling the two wafers to be bonded together with electrical interconnections being made at the aligned surface bonding pads.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates vias of a metallization layer and methods of fabricating same using a photolithography method and an imprint lithography method.

FIG. 2 diagrammatically illustrates a method of via fabrication using a replica mask.

FIG. 3 diagrammatically illustrates a method of via fabrication without using a replica mask.

FIG. 4 diagrammatically illustrates a method of fabrication of vias with designed three-dimensional geometry using repeated electron beam writing and etching of a master mask.

FIG. 5 diagrammatically illustrates a method of fabrication of retargeting vias using repeated electron beam writing and etching of a master mask.

FIG. 6 shows a flowchart of a method of using a master mask and replica masks for higher productivity of via fabrication by imprint lithography.

FIG. 7 shows a flowchart of a method of via fabrication using imprint lithography.

FIGS. 8A, 8B, 8C, 8D, and 8E show cut views after selected steps of the via fabrication method of FIG. 7.

FIG. 9 shows a flowchart of a method of fabrication of vias and a patterned metal layer using imprint lithography.

FIGS. 10A, 10B, 10C, 10D, 10E, 10F, 10G, 10H,, and 10I show cut views after selected steps of the via fabrication method of FIG. 9.

FIGS. 11A, 11B, 11C, 11D, and 11E illustrate some nonlimiting examples of three-dimensional via geometries obtainable using via fabrication with imprint lithography as disclosed herein.

FIG. 12 illustrates a cut view of example vias with labeled dimensions.

FIGS. 13A, 13B, 13C, and 13D illustrate formation of a metallization stack by repeated iterations of the via fabrication method of FIG. 7.

### DETAILED DESCRIPTION

The following disclosure provides various embodiments, or examples, for implementing various features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments disclosed herein provide vias, and methods of via fabrication, that enable or facilitate via retargeting. As used herein, via retargeting refers to the top of the via (i.e., where it intersects with an upper metallization Mx) having a different shape and/or being laterally shifted respective to the bottom of the via (i.e., where it intersects with a lower patterned metallization Mx-1). Such retargeting can provide improved flexibility in via routing in a metallization stack, can enable redistribution (e.g., spreading out) of the via connections at the patterned metallization Mx layer compared with the via connections at the patterned metallization Mx-1 layer, can improve the arrangement of bonding pads to which the vias connect, and/or provide other design advantages. In some embodiments herein, a combination of imprint lithography and anisotropic etching with low etch selectivity enables formation of such retargeted vias. By contrast, vias formed by photolithographic processes are difficult or impossible to retarget.

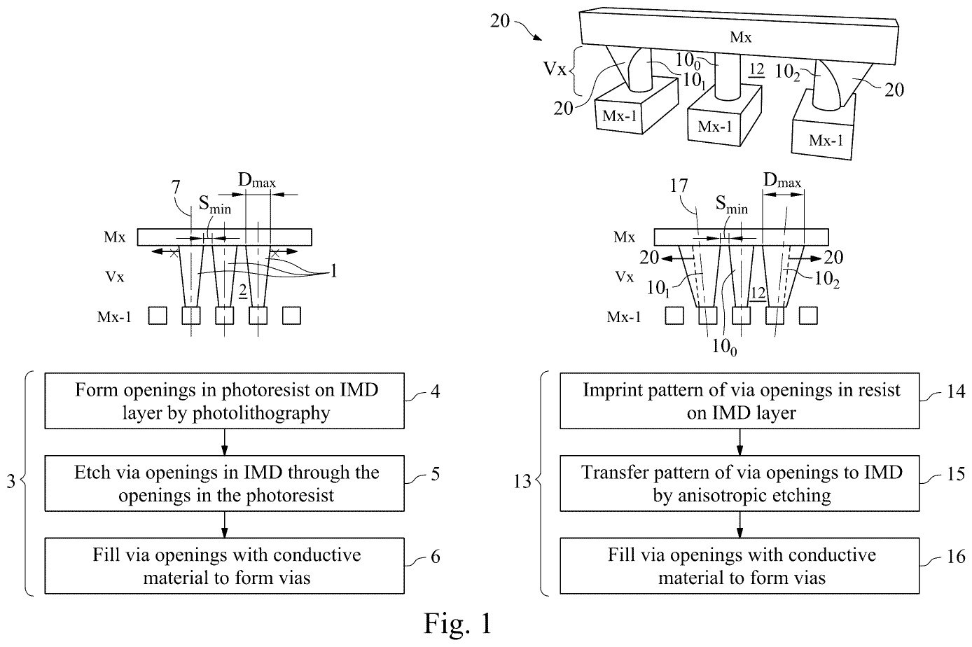

With reference to FIG. 1, a cut view is shown of photolithographically defined vias 1 that pass through an intermetal dielectric (IMD) layer 2 to connect a first (e.g., lower, Mx-1) patterned metal layer and a second (e.g., upper, Mx) patterned metal layer. The two metal layers Mx-1 and Mx may be neighboring layers of a metallization stack, and the photolithographically defined vias 1 are connecting vias of the metallization stack. The photolithographically defined vias 1 are formed by a photolithographic patterning process 3 including: an operation 4 in which openings are formed in a photoresist disposed on the IMD layer 2; an operation 5 in which via openings in the IMD 2 are etched through the openings in the photoresist; and an operation 6 in which the via openings in the IMD 2 are filled with a conductive material (e.g., copper, tungsten, or so forth) to form the vias 1. The photolithographically defined vias 1 have mutually parallel center lines 7. The mutually parallel center lines 7 of the photolithographically defined vias 1 are orthogonal to (i.e., perpendicular to) the surface of the IMD layer 2 coinciding with the Mx-1 layer. The mutually parallel center lines 7 of the photolithographically defined vias 1 are orthogonal to (i.e., perpendicular to) the surface of the IMD layer 2 coinciding with the Mx layer. The bottom and top of each photolithographically defined via 1 (i.e., “bottom and top” refer to where the photolithographically defined via 1 intersects the Mx-1 layer and the Mx layer, respectively) are vertically aligned with the central axis 7 of the photolithographically defined via 1. These geometrical characteristics of the photolithographically defined vias 1 are due to the nature of the formative photolithographic processing 4 and etching 5, which etches the via openings along mutually parallel etch directions starting from the respective photolithographically defined openings in the patterned photoresist layer.

FIG. 1 further illustrates vias 10₀, 10₁, and 10₂ formed in an IMD layer 12 using a different method 13, which also includes a lithography operation 14, an etching operation 15, and a via filling operation 16. In addition to a cut view of the vias 10₀, 10₁, and 10₂ and the Mx-1 and Mx patterned metallization layers, FIG. 1 also shows a perspective view 20 of the vias 10₀, 10₁, and 10₂ and the Mx-1 and Mx metallization layers. As the vias 20 connect between the Mx-1 and Mx patterned metallization layers, the vias 20 may also be referred to by the notation vias (Vx) or the like. The method 13 differs from the photolithographic method 3, in part in that the lithography operation 14 of the method 13 is not a photolithography operation, but rather is an imprint lithography operation 14 in which a pattern of via openings is imprinted in resist disposed on the IMD layer. Imprint lithography in the context of semiconductor integrated circuit (IC) manufacturing is sometimes referred to as nano imprint lithography (NIL), and hence the operation 14 may also be referred to herein as an NIL operation 14.

The photolithography operation 4 of the photolithographic via formation method 3 typically etches openings passing through the photoresist. By contrast, the NIL operation 14 imprints a pattern of via openings.

NIL uses a stamp to mechanically imprint features on a resist layer disposed on the semiconductor wafer, such as a monomer or polymer resist. In a nonlimiting illustrative NIL process for performing the NIL operation 14, the resist is spin coated onto the semiconductor wafer. The stamp is pressed onto the resist to mechanically transfer features of the stamp to the resist. While the stamp is pressed onto the resist, ultraviolet (UV) light is applied to cure the resist, after which the stamp is removed, leaving the cured resist with the mechanically transferred features. NIL can provide CD comparable to that obtainable by extreme ultraviolet (EUV) lithography at a lower cost. As a mechanical process, NIL can be impacted by mechanical distortion of the stamp and/or semiconductor wafer, thermal expansion or contraction, and the like. To provide overlay compensation in NIL, the stamp in some embodiments is adjusted by finger actuators arranged to press against the lateral edges of the stamp. The finger actuators may be piezoelectric actuators, electrostatic actuators, micro-stepper motors (e.g., implemented using MEMS), or the like. By adjusting the forces applied by the respective finger actuators, translational and rotational adjustment of the stamp can be implemented. If all the finger actuators press inward with increased force, this can provide negative magnification, whereas if all the finger actuators press inward with reduced force, this can provide positive magnification. To provide adjustment of the wafer to implement NIL overlay compensation, a laser or other light source in some embodiments illuminates a digital mirror device (DMD) to apply different levels of light to different portions of the IC die to generate a heat distribution that leads to thermal expansion or contraction. These are merely some nonlimiting illustrative examples of NIL.

As will be further described herein, the pattern of via openings produced by the NIL operation 14 is different from the photolithographically formed openings produced by the operation 4 in at least two respects: the pattern of via openings produced by the NIL operation 14 does not necessarily pass through the resist layer; and the pattern of via openings produced by the NIL operation 14 constitutes a three-dimensional representation (i.e., imprint) of the three-dimensional shape of the via openings to be formed. The imprint lithography operation 14, along with suitable design of the subsequent etching operation 15, advantageously enables formation of the via openings in the IMD 12 with designed three-dimensional geometries, so that when the via openings are filled in the operation 16 the resulting vias 10₀, 10₁, and 10₂ also have designed three-dimensional geometries.

With reference back to the cut view and perspective view 20 of the vias 10₀, 10₁, and 10₂, in this nonlimiting illustrative example the vias 10₀, 10₁, and 10₂ have center lines 17 which are not mutually parallel. This is because the outer two vias 10₁ and 10₂ include additional portions 20 that shift their respective center lines 17 outward respective to the central via 10₀. This asymmetrically enlarges the tops of the outer two vias 10₁ and 10₂ respective to their bottoms, and laterally shifts the tops of the outer two vias 10₁ and 10₂ outward (i.e., away from the central via 10₀) respective to their bottoms.

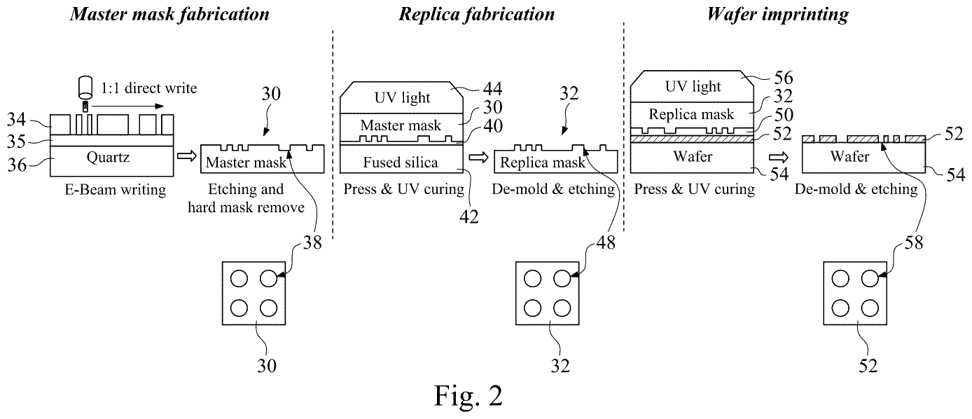

With reference now to FIG. 2, in a further optional aspect, a master mask 30 may be provided, and a mask 32 used to form the imprint pattern of via openings in resist in the operation 14 of FIG. 1 may in some embodiments be a “replica” mask 32 which is produced using the master mask 30. FIG. 2 diagrammatically shows a nonlimiting example of such a process. As depicted in the “Master Mask Fabrication” portion in the left of FIG. 2, the master mask 30 is fabricated by applying an electron beam (e-beam) resist 34 on a substrate 36 (e.g., an illustrative quartz substrate 36, although other suitably rigid substrate materials are contemplated) and performing e-beam writing of a pattern on the resist. (Note, the example of FIG. 2 includes an optional adhesion layer 35, for example comprising a polymer and additives for hydrophilicity adjustment, to improve adhesion of the resist 34 to the substrate 36. Such an adhesion layer may be omitted if the resist adheres sufficiently well to the substrate without it.) The e-beam-written pattern is removed by developing the e-beam resist using a suitable developer, and subsequent etching forms recesses 38 aligned with the e-beam-written openings, after which the e-beam resist is removed using a suitable e-beam resist stripper. (Note that the lefthand diagram of FIG. 2 illustrates a side sectional view of the master mask 30 with the recesses 38, and also a top view of a portion of the master mask 30 showing four illustrative recesses 38.)

The middle portion of FIG. 2 illustrates the “Replica fabrication”. As shown there, a resist layer 40 is formed on a replica mask substrate 42 (e.g., an illustrative fused silica replica mask substrate 42, although other suitably rigid substrate materials are contemplated), and the master mask 30 is pressed onto the resist 40 to imprint (a reverse of) the pattern of recesses of the master mask 30 on the resist 40. The imprinted pattern is reversed in that the recesses 38 of the master mask 30 are imprinted as protrusions in the resist 40. The resist 40 with the imprinted pattern of protrusions is cured using ultraviolet (UV) light 44, and thereafter the master mask 30 is removed. An anisotropic etch with low selectivity between the material of the resist 40 and the material of the substrate 42 is performed, which transfers the pattern of protrusions imprinted on the resist 40 to the replica mask substrate 42, thus producing the replica mask 32 with the transferred protrusions 48. (Note that the middle diagram of FIG. 2 illustrates a side sectional view of the replica mask 32 with the protrusions 48, and also a top view of a portion of the replica mask 32 showing four illustrative protrusions 48.)

The right portion of FIG. 2 illustrates the “Wafer imprinting”, corresponding to operations 14 and 15 of the method 13 of FIG. 1. As shown there, a resist layer 50 is formed on an intermetal dielectric (IMD) layer 52 disposed on a semiconductor wafer 54. The replica mask 32 is pressed onto the resist 50 to imprint (a reverse of) the pattern of protrusions of the replica mask 32 on the resist 50. The imprinted pattern is reversed in that the protrusions 48 of the replica mask 32 are imprinted as recesses in the resist 50. The resist 50 with the imprinted pattern of recesses is cured using UV light 56, and thereafter the replica mask 32 is removed. An anisotropic etch with low selectivity between the material of the resist 50 and the dielectric material of the IMD layer 52 is performed, which transfers the pattern of recesses imprinted on the resist 50 to the IMD layer 52, thus transferring the pattern of recesses to the IMD material 52 to form via openings 58 in the IMD layer 52. (Note that the right diagram of FIG. 2 illustrates a side sectional view of the final wafer 54 with the IMD layer 52 having the recesses 58, and also a top view of a portion of the IMD layer 52 showing four illustrative recesses 58.)

In the example of FIG. 2, the master mask 30 is used to produce a replica mask 32 which is then used in the imprint operation 14 of FIG. 1. This has certain advantages. Notably, the manufacture of the master mask 30 may be complex (as will be further detailed later herein), but the manufacture of the replica mask 32 entails a relatively straightforward imprint operation. Advantageously, a single master mask 30 can be used to fabricate a plurality of replica masks 32.

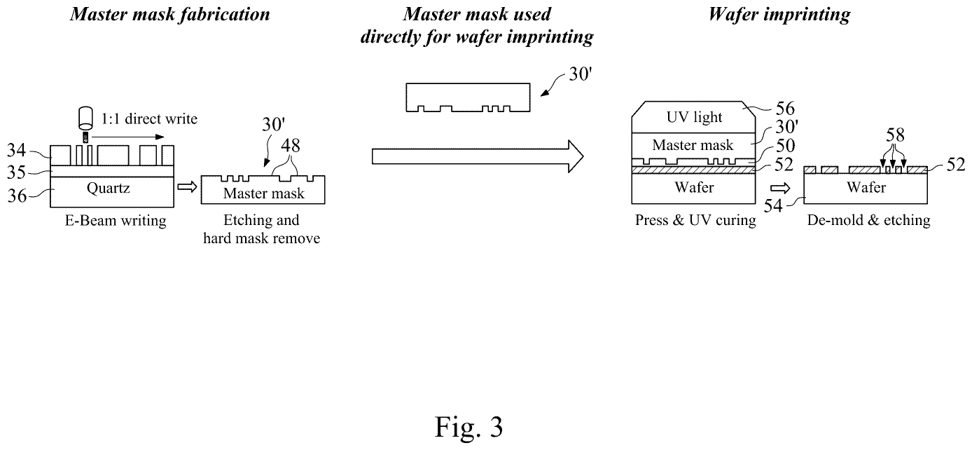

With reference to FIG. 3, however, it is alternatively contemplated to directly use the master mask 30 for the imprint operation 14 of FIG. 1. FIG. 3 illustrates this processing flow, which includes the Master mask fabrication shown on the lefthand side of FIG. 3 and corresponding to the Master mask fabrication of FIG. 2. However, in the example of FIG. 3 this produces a variant master mask 30′ in which the e-beam-written pattern comprises the protrusions 48. As shown on the right of FIG. 3, the wafer imprinting uses the (variant) master mask 30′ to imprint the pattern of via openings on the resist 50 disposed on the IMD layer 52, and the anisotropic and low selectivity etch then transfers the imprinted pattern of via openings to the IMD layer 52 to form the via openings 58. Hence, as illustrated in FIG. 3, the replica mask 32 may optionally be omitted in the process flow.

Returning to the example of FIG. 2 which does employ the replica mask 32, the recesses 38 of the master mask 30 have straight sidewalls, and hence the protrusions 48 of the replica mask 32 have straight sides and the via openings 58 have straight sides. However, by employing repeated iterations of e-beam writing and etching in the master mask fabrication, a pattern of via openings can be formed on the surface of the master mask 30, thereby enabling the resulting via openings to have designed three-dimensional geometries.

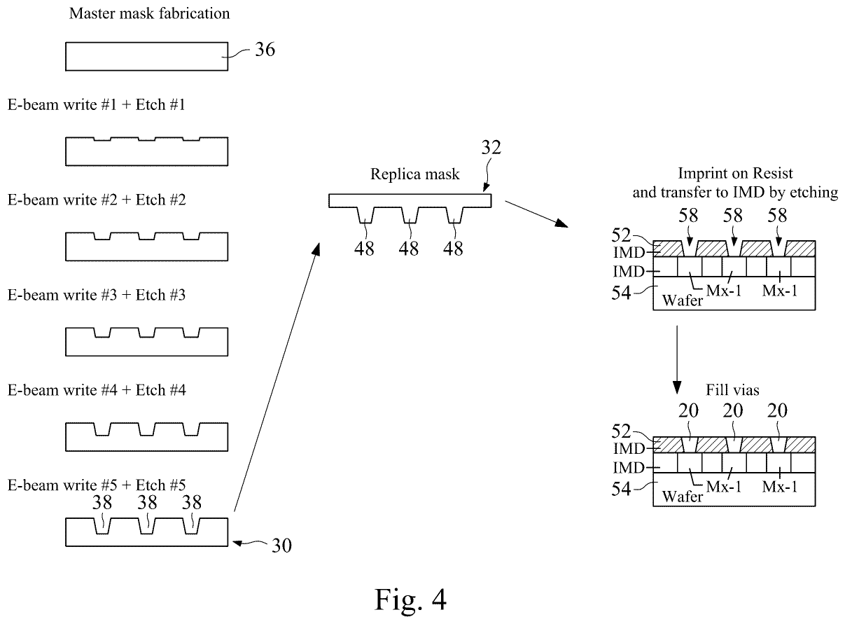

With reference to FIG. 4, a nonlimiting illustrative example of this is shown, which implements via openings with slanted sidewalls. As shown in the lefthand side of FIG. 4, the substrate 36 (e.g., a quartz substrate in some nonlimiting examples) undergoes a first e-beam writing and etching iteration labeled “E-beam write #1+Etch #1”, which forms (relatively) large diameter but shallow recesses in the substrate 36. This is followed by a second e-beam writing and etching iteration labeled “E-beam write #2+Etch #2”, which forms slightly smaller diameter shallow recesses within the initial shallow recesses formed by the initial “E-beam write #1+Etch #1” iteration. This process repeats with an “E-beam write #2+Etch #2” iteration, “E-beam write #3+Etch #3” iteration, “E-beam write #4+Etch #4” iteration, and a final “E-beam write #5+Etch #5” iteration, with each successive iteration forming a smaller diameter recess within the previously formed recess. As seen in the diagram of FIG. 4 showing the final master mask 30 after the final “E-beam write #5+Etch #5” iteration, the resulting recesses 38 have slanted sidewalls. The replica imprint then forms corresponding protrusions 48 on the replica mask 32. As seen on the righthand side of FIG. 4, the “Imprint on Resist and transfer to IMD by etching” step (corresponding to operations 14 and 15 of the via fabrication method 13 of FIG. 1) forms via openings 58 with slanted sidewalls analogous to the slanted sidewalls of the recesses 38 of the master mask 30. FIG. 4 further shows the result of a final operation 16 of FIG. 1, i.e., “Fill vias”, in which the via openings 58 are filled with an electrically conductive material (e.g., copper, tungsten, et cetera) to form vias 20 passing through the IMD layer 52. The vias 20 have slanted sidewalls corresponding to the slanted sidewalls of the via openings 58.

In the example of FIG. 4, the successive “E-beam write +Etch” iterations etch recesses that are of successively smaller diameter but which are concentric with each other. This produces the final recesses 38 which are conical in shape with circular upper and lower cross-sections (and circular cross-sections at every point in-between). However, by shifting the successively etched recesses laterally, more complex via opening geometries can be formed.

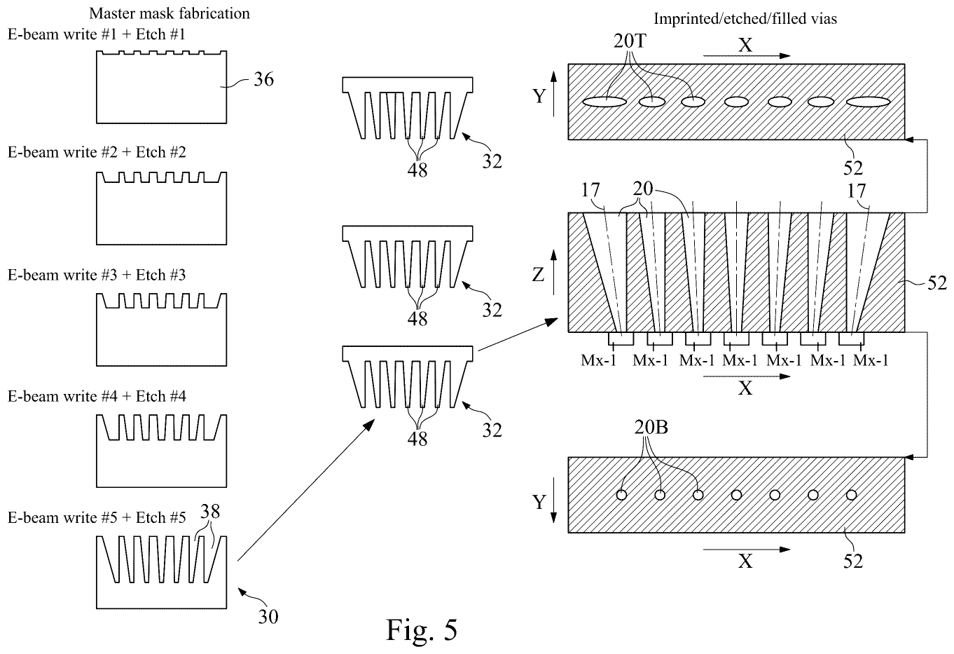

With reference now to FIG. 5, a further nonlimiting illustrative example is shown, which illustrates how the via formation method 13 of FIG. 1 can be used to form vias whose center lines 17 are not mutually parallel. The lefthand side of FIG. 5 shows the fabrication of the master mask 30 using a five-iteration etch sequence including initial “E-beam write #1+Etch #1” iteration, then an “E-beam write #2+Etch #2” iteration, then “E-beam write #3+Etch #3” iteration, “E-beam write #4+Etch #4” iteration, and a final “E-beam write #5+Etch #5” iteration. As further seen in the center portion of FIG. 5, by shifting the successively etched recesses laterally, the center lines of the resulting recesses 38 can be designed with center lines that extend increasingly outward for recesses closer to the periphery. FIG. 5 also diagrammatically shows imprinting multiple (illustrative three) replica masks 32, each with a pattern of protrusions 48 corresponding to the recesses 38 of the master mask. The righthand portion of FIG. 5 shows the final vias 20 passing through the IMD 52 (i.e., corresponding to the result of operation 16 of FIG. 1). The center lines 17 of the vias 20 are also indicated, and it is seen that the center lines 17 of the vias 20 are not mutually parallel-rather, the centerline is slanted at an increasingly large angle away from the vertical with increasing distance from the center of the set of vias 20.

FIG. 5 also diagrammatically shows a top view showing the tops 20T of the vias 20, and a bottom view showing the bottoms 20B of the vias 20. To provide description of the orientation, X-Y-Z directions are indicated. As labeled, the cross section showing the center lines 17 of the vias 20 is an X-Z cut plane. The via tops 20T are shown by an X-Y plane, and the via bottoms 20B are shown in an X-(-Y) plane. As seen in these drawings, the bottoms 20B of the vias 20 have circular cross-sections, and are uniformly spaced along the X-direction. The tops 20T of the vias 20, by contrast, are spread out along the X-direction, with vias further away from the center of the set of vias having increasing length of the via top 20T. On the other hand, the via tops 20T have the same length in the Y-direction as the via bottoms 20B. Hence, the via tops 20T are not circular, but rather are ellipses with the long axis of each via top 20T along the X-direction and the short axis along the Y-direction. (Although not shown, in some examples the via tops 20T may connect with, and hence intersect, the Mx patterned metal layer.) FIG. 5 illustrates another feature of the vias 20 that can be designed, namely, the shapes of the tops of the vias can be designed to be different (here non-circular elliptical) than the shapes of the bottoms of the vias (here circular). It will be appreciated that other via top and bottom shapes can be designed, including rectangular or square via tops and/or bottoms as further nonlimiting examples.

In general, the vias can be retargeted. The vias 20 of FIG. 5, with the exception of the central via, are retargeted vias. The retargeting via can in some examples (such as FIG. 5) have a noncircular cross-section at its intersection with the second (e.g., Mx) patterned metal layer. The retargeting via can in some examples (such as FIG. 5) have a circular cross-section at its intersection with the first (e.g., Mx-1) patterned metal layer and a noncircular cross-section at its intersection with the second (e.g., Mx) patterned metal layer. The retargeting via can in some examples (such as FIG. 5) have its intersection with the second (e.g., Mx) patterned metal layer laterally offset from its intersection with the first (e.g., Mx-1) patterned metal layer. This offset is a consequence of the center lines 17 of the retargeted vias not being perpendicular to a surface of the dielectric layer (e.g., IMD layer 52) on which the second patterned metal layer is disposed.

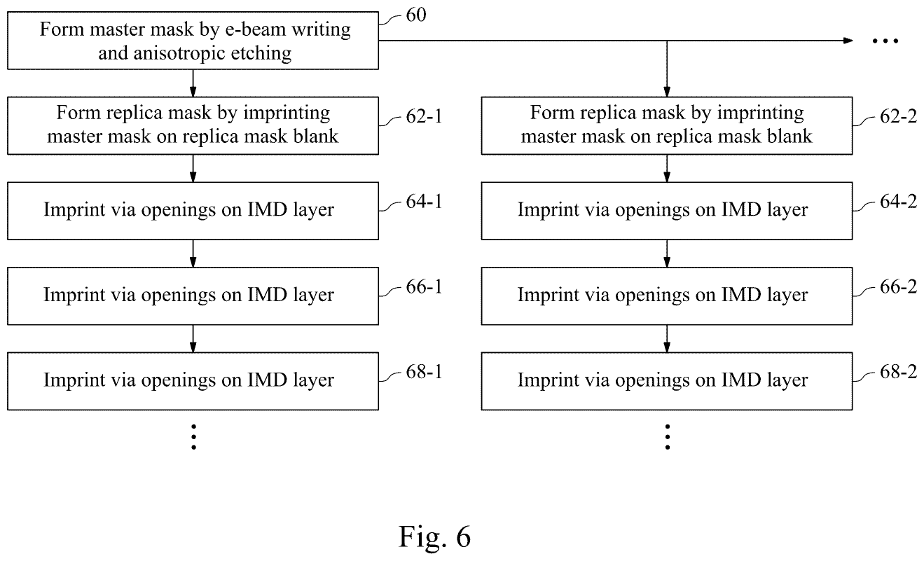

With reference now to FIG. 6, an overall process flow employing both a master mask 30 and one or more replica masks 32 is described. In an operation 60, the master mask is formed by e-beam writing and anisotropic etching, e.g., as described by way of examples referring to FIGS. 2, 4, and 5. Notably, the operation 60 may be performed only once to produce a single master mask 30. Thereafter, in an operation 62-1 a replica mask may be formed by imprinting the master mask on a replica mask blank, e.g., by imprinting followed by anisotropic and low selectivity etching as described by way of examples referring to FIGS. 2 and 4. Advantageously, this replica mask formation may be repeated, as indicated in FIG. 6 by a second instance 62-2 of replica mask formation. More generally, one, two, three, four, five, or more replica masks may be formed by imprinting and suitable etching of respective replica mask substrates. After each replica mask 32 is formed, it may be used to imprint via openings 58 in the IMD layer 52 of successive wafers, as indicated in FIG. 6 by successive via openings imprint operations 64-1, 66-1, 68-1, . . . using the replica mask fabricated in operation 62-1; and similarly successive via openings imprint operations 64-2, 66-2, 68-2, . . . using the replica mask fabricated in operation 62-2. Thus, a single master mask 30 may be used to imprint a number of replica masks 32, each of which may be used to imprint via openings (corresponding to operation 14 of FIG. 1). This advantageously enables rapid upscaling of the via formation process.

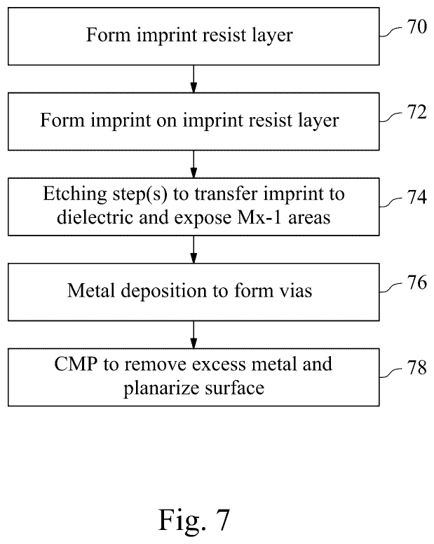

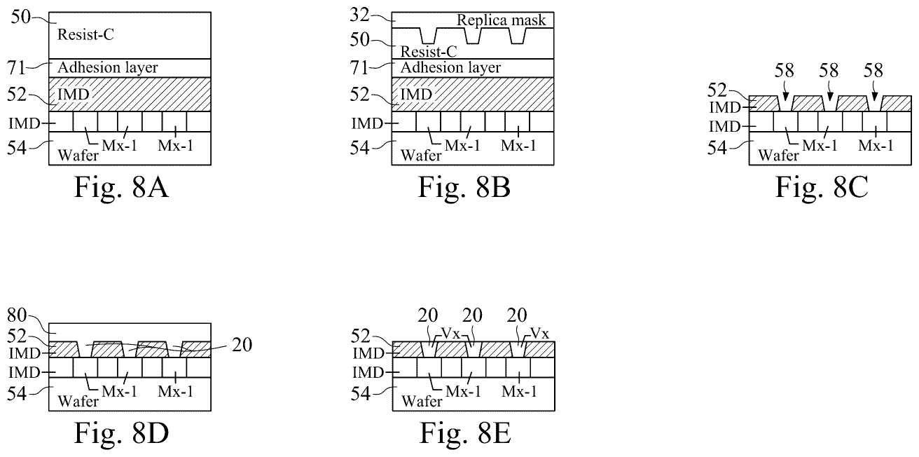

With reference now to a flowchart shown in FIG. 7 and successive cut views shown in FIGS. 8A, 8B, 8C, 8D, and 8E, another example of the via formation process 13 of FIG. 1 is described, which provides further description of some illustrative approaches for performing the via filling operation 16. In an operation 70, the resist layer 50 is formed on the IMD layer 52 disposed on the wafer 54. For example, in some embodiments the resist layer 50 is spun on. In some embodiments there may be multiple resist layers—the term imprint resist layer 50 is used here to identify the topmost resist layer 50 into which the replica mask 32 will imprint. FIG. 8A illustrates a cut view of the wafer after operation 70. In the example of FIG. 8A, an adhesion layer 71 is applied prior to the imprint resist layer 50 to promote adhesion.

In an operation 72 (corresponding to operation 14 of FIG. 1), the imprint is formed on the imprint resist layer 50 by pressing the replica mask 32 onto the imprint resist layer 50 to transfer the pattern of via openings (e.g., represented by protrusions 58 and recesses between the protrusions) to the resist layer 50. The operation 72 may also optionally include a UV curing step, e.g., as illustrated in FIG. 2 (“Wafer imprinting”), and the subsequent removal of the replica mask 32. FIG. 8B illustrates a cut view after the replica mask 32 is pressed onto the imprint resist layer 50 but before the subsequent removal of the replica mask. In an operation 74 (corresponding to operation 15 of FIG. 1), an anisotropic and nonselective etch is performed to transfer the pattern of via openings from the resist layer 50 to the IMD layer 52, resulting in the cut view shown in FIG. 8C. The etch is anisotropic in that it preferentially etches downward rather than laterally, and is nonselective in that it etches the material of the resist layer 50 and the dielectric material of the IMD layer 52 with about the same etch rate. In some nonlimiting examples, the etching used in the operation 74 may be a dry plasma etch employing one or more etchants such as C, O, H, Cl, or F based etchant gases. The particular choice of etch can be optimized for a particular type of resist and particular IMD material. (Note, the adhesion layer 71 is typically thin and also etched away in the operation 74.) The transferred pattern of via openings 58 are shown in FIG. 8C.

The via filling operation 16 of FIG. 1 corresponds to a metal deposition operation 76 of FIG. 7. The operation 76 may, for example, employ copper electroplating to fill the via openings 58 with conductive material (here, copper) to form the vias 20. In other embodiments, physical vapor deposition (PVD) may be used. The operation 76 also deposits excess copper 80 on the surface of the IMD layer 52. FIG. 8D shows a cut view after the operation 76. In an operation 78, chemical mechanical polishing (CMP) is performed to remove the excess conductive material 80 and planarize the surface and expose the tops of the vias 20, resulting in the structure shown in FIG. 8E. Subsequent processing (not shown) may, for example, deposit and pattern a metal layer to form the Mx layer contacting the tops of the vias 20. In another example of subsequent processing (not shown), if the IMD layer 52 is the topmost layer then bonding pads may be formed on its surface in contact with the vias (Vx).

In some other embodiments, the excess metal 80 deposited on the surface of the IMD layer 52 is leveraged to form the Mx patterned metallization layer.

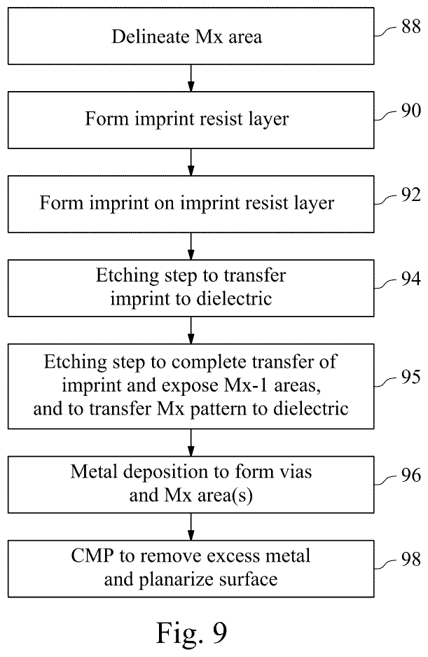

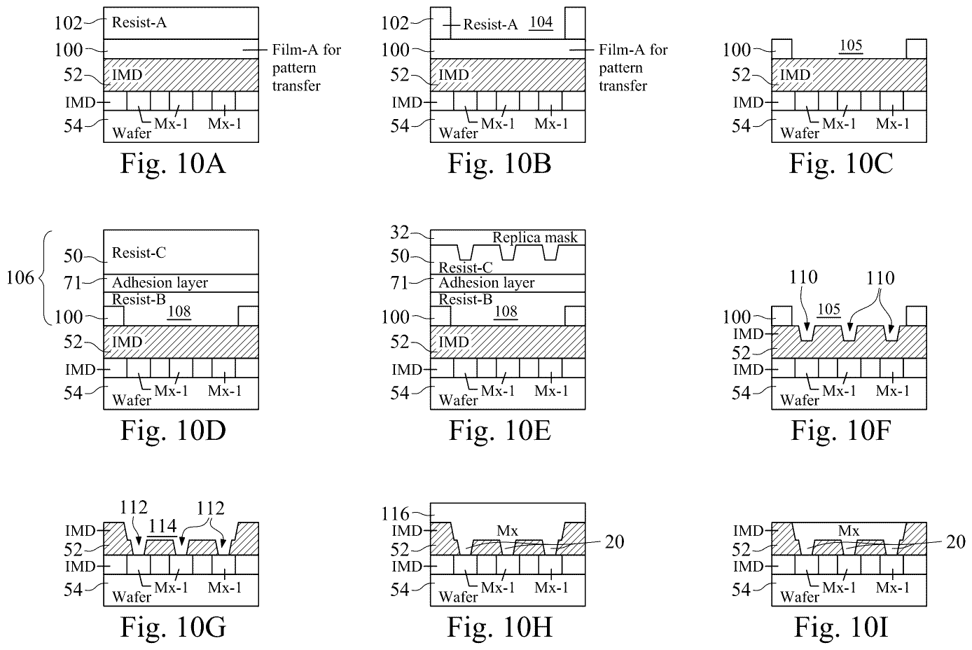

With reference now to a flowchart shown in FIG. 9 and successive cut views shown in FIGS. 10A, 10B, 10C, 10D, 10E, 10F, 10G, 10H,, and 10I, an example of a variant via formation process is described, which forms the Mx metallization layer concurrently with the vias by leveraging the excess metal deposited on the surface. In an initial operation 88 illustrated by cut views 10A, 10B, and 10C, the Mx metallization layer is delineated. To this end, a layer 100 (labeled as “Film-A” in FIGS. 10A and 10B) and a first resist layer 102 are formed over the dielectric layer 52. The result after these depositions is diagrammatically shown in FIG. 10A (where the first resist layer 102 is labeled “Resist-A”). In a nonlimiting illustrative example, Film-A 100 is a dielectric material that contains Si, C, H, O, N, or so forth, and is applied by chemical vapor deposition (CVD) or a spin-on technique. While a single layer is shown, Film-A 100 could comprise two (or more layers), e.g., containing Si, O, N, and/or so forth. First resist layer 102 may be a photoresist, for example containing C, H, O, or so forth. A photolithography step patterns the first resist layer 102. For example, the photolithographic exposure may employ deep ultraviolet (DUV) exposure, extreme ultraviolet (EUV) exposure, or so forth, followed by development of the latent image using a developer suitable for the type of photoresist used. The result of the photolithographic exposure and development is shown in FIG. 10B, where an illustrative opening 104 in the first resist layer 102 is shown. It should be noted that while a single opening 104 is shown by diagrammatic example, the opening 104 could represent a pattern of openings, for example to ultimately define a patterned Mx metallization layer. Put another way, the opening 104 represents the Mx metallization pattern. Dry etching is then performed to transfer the pattern from the developed Resist-A 102 to Film-A 100, producing the structure shown in FIG. 10C. As seen there, the illustrative opening 104 is transferred to Film-A 100 as opening 105 in Film-A 100. Again, while a single opening 105 is shown by diagrammatic example, the opening 105 could represent a pattern of openings, for example to ultimately define a patterned Mx metallization layer. Put another way, the opening 105 represents the Mx metallization pattern. In one nonlimiting illustrative embodiment, the etching performed to transfer the pattern from the developed Resist-A 102 to Film-A 100 may comprise dry plasma etching using an etchant based on C, O, H, Cl, F, or so forth, as appropriate for etching the material of Film-A 100.

With reference back to FIG. 9, operation 88 is followed by operations 90 and 92 which are similar or identical to the corresponding respective operations 70 and 72 of FIG. 7. In operation 90, an imprint resist layer 106 is formed. In this nonlimiting illustrative example, the imprint resist layer 106 includes the resist layer 50 corresponding to resist layer 50 of the embodiment of FIGS. 7 and 8A and 8B (also labeled as “Resist-C” in FIGS. 10D and 10E) and its underlying optional adhesion layer 71; but imprint resist layer 106 of the embodiment of FIG. 9 further includes an underlying resist layer 108 (also labeled as “Resist-B” in FIGS. 10D and 10E). Resist-B 108 is an optional layer that may be included to improve topography (fill plat), and may for example comprise a dielectric material containing C, H, O, or so forth. The adhesion layer 71 provides better adhesion between Resist-B and Resist-C. Adhesion layer 71 may contain C, H, O, or so forth. As in the example of FIG. 7, the Resist-C layer 50 is the layer into which the NIL imprints. FIG. 10D diagrammatically shows the structure after the imprint resist layer 106 is formed according to the operation 90. In an operation 92, the imprint is formed on the imprint resist layer 50 by pressing the replica mask 32 onto the imprint resist layer 50 to transfer the pattern of via openings to the resist layer 50. The operation 92 may also optionally include a UV curing step. The replica mask 32 is subsequently removed. FIG. 10E illustrates a cut view after the replica mask 32 is pressed onto the imprint resist layer 50 but before the subsequent removal of the replica mask.

In an operation 94, an anisotropic and nonselective etch is performed to transfer the pattern of via openings from the resist layer 50 to the IMD layer 52, resulting in the cut view shown in FIG. 10F. As there seen, the anisotropic and nonselective etch removes the imprint resist layer 106 (including removal of the Resist-C layer 50, adhesion layer 71, and Resist-B layer 108), and continues non-selectively etching into the IMD 52 to produce partial via openings 110. It is noted, however, that the partial via openings 110 do not extend fully through the IMD layer 52 to expose the Mx-1 patterned metallization regions. Furthermore, the (first) etching operation 94 does not etch the patterned Film-A 100 which is destined to define the Mx patterned metallization layer. The etch of operation 94 is anisotropic in that it preferentially etches downward rather than laterally, and is nonselective in that it etches the materials of the imprint resist layer 106 (including resist layers 50 and 108 and adhesion layer 71) and the dielectric material of the IMD layer 52 with about the same etch rate (thereby forming the partial via openings 110). As just noted, however, the etch of operation 94 is selective insofar as it does not etch the patterned Film-A 100. In some nonlimiting examples, the etching used in the operation 94 may be a dry plasma etch employing one or more etchants such as C, O, H, Cl, or F based etchant gases. The particular choice of etch can be optimized for a particular type of resist and particular IMD material. As labeled in FIG. 10F, since the etching operation 94 removes the imprint resist layer 106 but does not etch the patterned Film-A 100, etching operation 94 also reopens the Mx metallization pattern 105.

In an operation 95, a second etching step is performed to complete transfer of the imprinted via openings to the IMD 52 so as to form via openings 112 that pass fully through the IMD layer 52 to expose the Mx-1 areas. The etching of operation 95 is anisotropic in that it etches preferentially downward rather than laterally. However, since the imprint resist layer 106 was removed in the previous etching operation 94, the etching operation 95 is not necessarily nonselective between the material of the IMD 52 and the materials of the imprint resist layer 106. Rather, the etching 95 is nonselective between the material of the IMD layer 52 and the material of the patterned Film-A 100. Said another way, the etching used in the operation 95 etches both the IMD layer 52 and the patterned Film-A 100 with approximately similar etch rates. The cut view of FIG. 10G illustrates the result of the second etching operation 95. As there seen, in addition to completing the transfer of the imprinted via openings to the IMD 52 so as to expose the Mx-1 areas (by way of via openings 112), the second etching operation 95 also transfers the Mx metallization pattern 105 from the patterned Film-A 100 to the IMD 52 as illustrative opening 114. Again, while a single opening 114 is shown by diagrammatic example, the opening 114 may represent a pattern of openings. For example, opening 114 may constitute the Mx metallization pattern 114.

In an operation 96, a metal deposition is performed, which deposits metal that fills the via openings 112 to form the vias 20, and that also fills the opening(s) 114 to form the Mx metallization. This is shown in cut view 10H, where it is seen that the deposited metal 116 overfills the openings 112 and 114 to produce excess metal 116 on the wafer surface. The operation 96 may, for example, employ copper electroplating to fill the via openings 112 and 114 with conductive material (here, copper) to form the vias 20 and Mx patterned metallization. In other embodiments, PVD may be used. In an operation 98, CMP is performed to remove the excess conductive material 116 and planarize the surface and expose the Mx metallization, resulting in the structure shown in FIG. 10I. Compared with the process of FIG. 7, the process of FIG. 9 thus advantageously forms both the vias 20 and the Mx metallization.

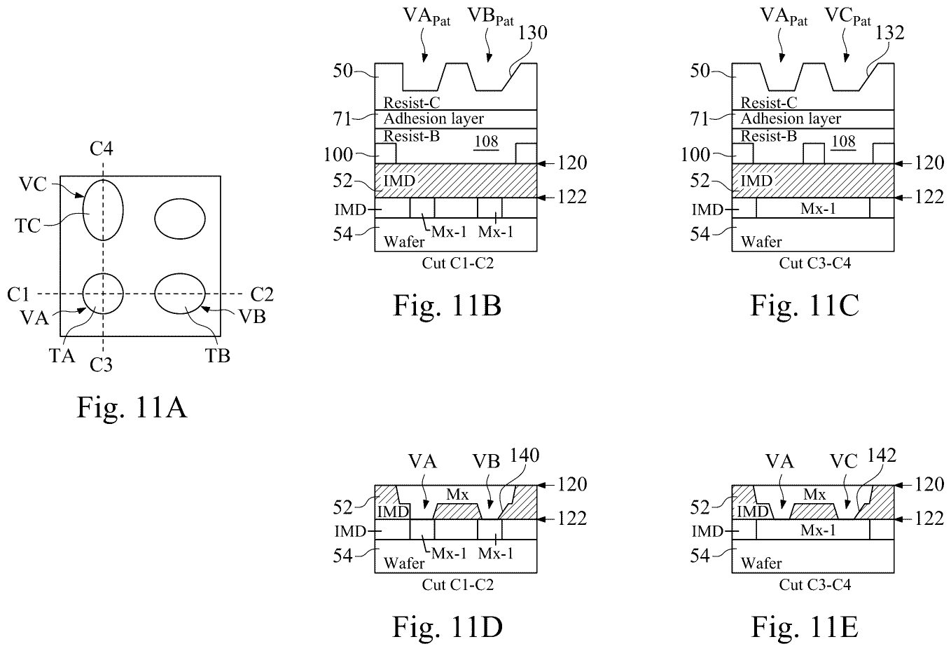

With reference now to FIGS. 11A, 11B, 11C, 11D, and 11E, some nonlimiting illustrative examples of three-dimensional via geometries that can be fabricated using the NIL-based via formation method of FIG. 9 are diagrammatically shown. FIG. 11A shows a top (i.e., plan) view of four vias, including three vias VA, VB, and VC discussed here, with the upper (Mx) metallization omitted to reveal the tops of the vias VA, VB, and VC. FIG. 11A also shows two cut lines: a cut C1-C2 and a cut C3-C4. FIGS. 11B and 11C show cut C1-C2 and cut C3-C4, respectively, taken after imprinting a pattern of via openings on the imprint resist (Resist-C) 50, including via patterns VAₚₐₜ, VBₚₐₜ, and VCₚₐₜ destined to form vias VA, VB, and VC respectively. FIGS. 11B and 11C correspond to FIG. 10E, but after removal of the replica mask 32. FIGS. 11D and 11E show cuts C1-C2 and C3-C4, respectively, taken after the final CMP 98 of FIG. 9, and show vias VA, VB, and VC respectively. FIGS. 11D and 11E correspond to FIG. 10I.

As labeled in each of FIGS. 11B, 11C, and 11D, the IMD layer 52 has an upper surface 120 distal from the substrate (e.g., wafer) 54, and a lower surface 122 proximal to the substrate 54. Each of the Vias VA, VB, and VC have a circular cross-section at the lower surface 122, where the vias intersect with the lower (Mx-1) patterned metallization layer. Prior to filling with the metal, the via openings corresponding to vias VA, VB, and VC respectively have circular lower apertures at the lower surface 122 of the IMD layer 52.

Each of the Vias VA, VB, and VC also has an upper end (or top) labeled in FIG. 11A as TA, TB, and TC for vias VA, VB, and VC, respectively. (As previously noted, FIG. 11A omits the Mx patterned metallization so as to reveal the via tops TA, TB, and TC). Prior to the via openings being filled with the metal, the via openings corresponding to vias VA, VB, and VC respectively have circular upper apertures at the upper surface 120 of the IMD layer 52 which correspond to the via tops TA, TB, and TC.

Considering first via VA, this via has its upper end (or top) TA that is circular and that is concentric with the lower end (or bottom) of the via VA; but with the upper end (or top) TA being larger than the lower end (or bottom) of the via VA. This via is not being retargeted, although having the larger top TA may facilitate bonding or other connection to the via VA.

The vias VB and VC are retargeting vias, in which the respective via tops TB and TC have centers which are laterally offset from the centers of the via bottoms. Via VB has a noncircular (illustrative elliptical) top TB that is laterally offset from its bottom along the C1-C2 cut line, as seen in FIG. 11D (and as seen for the corresponding pattern VB_{Pat} in FIG. 11B), namely laterally offset to the right in the drawings. On the other hand, via top TB of via VB is aligned with its bottom along the C3-C4 cut line.

Via VC has a noncircular (illustrative elliptical) top TC that is laterally offset from its bottom along the C3-C4 cut line, as seen in FIG. 11E (and as seen for the corresponding pattern VC_{Pat} in FIG. 11E), namely laterally offset to the right in the drawings. On the other hand, via top TC of via VC is aligned with its bottom along the C1-C2 cut line.

FIGS. 11A-11E are merely nonlimiting illustrative examples, and the retargeting vias can be laterally shifted in other directions, and/or can have via tops with different shape (e.g., rectangular or square as further examples). The use of NIL enables a wide range of three-dimensional geometries for the retargeting vias. In general, the pattern of the patterned mask (that is, the pattern of via openings of the replica mask 32) may include at least one slanted surface (e.g., producing imprinted slanted surfaces 130 and 132 in the examples of FIGS. 11B and 11C), and the etching transfers the slanted surface to the dielectric layer (e.g., IMD layer 52), so that when the via openings transferred to the dielectric layer 52 are filled in with the copper or other conductive material this produces the vias with slanted surfaces (e.g., slanted surface 140 of via VB and slanted surface 142 of via VC).

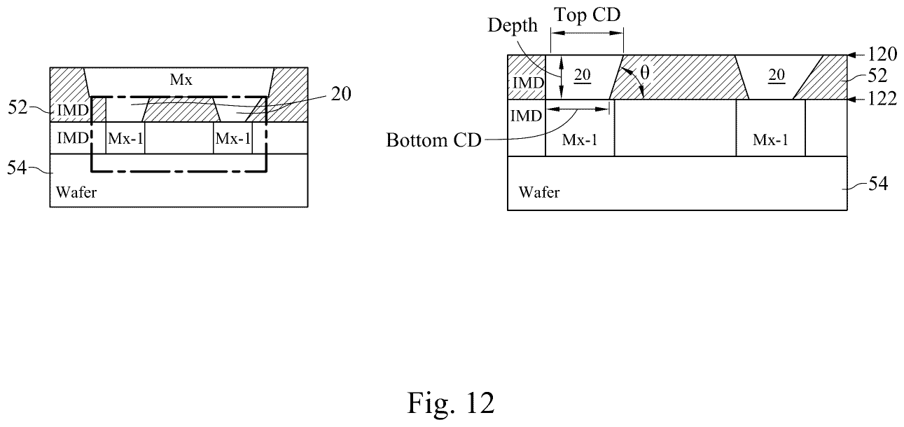

With reference now to FIG. 12, representative retargeting vias 20 are shown, with annotations labeling the via Depth (which equals the thickness of the IMD layer 52), bottom critical dimension (CD), and top CD, for one illustrative via, along with an angle θ of a sidewall of the labeled via. In some nonlimiting illustrative examples, these dimensions may have values in the following ranges: the top CD (at top 120 of IMD layer 52) larger than the bottom CD; the top CD being on the order of 1000 nm in some examples; the bottom CD (at bottom 122 of IMD layer 52) being in a range of 10 nm to 1000 nm; a thickness of IMD layer 52 (corresponding to the Depth of the via) in a range of 10 nm to 10,000 nm); a ratio of the top CD/bottom CD ratio in a range of 1 to 100; a via depth/top CD ratio in a range of 0.01 to 100; and the sidewall angle θ in a range of between 30 degrees and 90 degrees. These are merely some nonlimiting illustrative examples, and values outside these example ranges are contemplated.

The foregoing examples have illustrated a single layer of vias (Vx) between a lower (Mx-1) metallization layer and an upper (Mx) metallization layer. It will be appreciated that this can be extended to two, three, or more via layers.

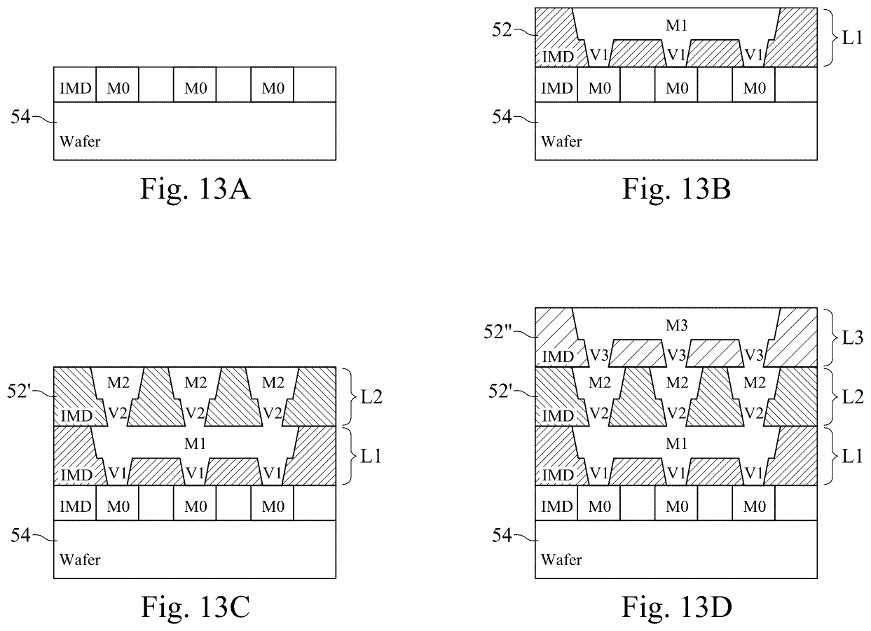

With reference to FIGS. 13A, 13B, 13C, and 13D, an example of such multiple via layers is illustrated. FIG. 13A illustrates a cut view of a wafer 54 with an M0 patterned metallization layer formed thereon. FIG. 13B shows a cut view of the wafer 54 after fabrication of a first layer L1 of vias V1 connecting the (here lower) M0 patterned metallization layer with a (here upper) M1 patterned metallization layer. The vias V1 and the M1 patterned metallization layer may be fabricated, for example, in accordance with the method of FIG. 9, with FIG. 13B corresponding to FIG. 10I produced after the final CMP step 98 of the method of FIG. 9.

For the fabrication of a second via layer L2, the M1 patterned metallization layer is now the lower metallization layer. A second IMD layer 52′ is formed on the M1 metallization layer, and the method of FIG. 9 is repeated, with FIG. 13C corresponding to FIG. 10I produced after the final CMP step 98 of the second repetition of the method of FIG. 9. This produces a layer of vias V2 connecting with an M2 patterned metallization layer, as shown in FIG. 13C. (Note that in this example, the M2 patterned metallization layer is patterned into three portions along the cut line aligned with respective V2 vias).

For the fabrication of a third via layer L3, the M2 patterned metallization layer is now the lower metallization layer. A third IMD layer 52″ is formed on the M2 metallization layer, and the method of FIG. 9 is again repeated, with FIG. 13D corresponding to FIG. 10I produced after the final CMP step 98 of the third repetition of the method of FIG. 9. This produces a layer of vias V3 connecting with an M3 patterned metallization layer, as shown in FIG. 13D. It will be appreciated that this process can be repeated for an arbitrary number of via layers N. Moreover, if the vias of successive layers are retargeted along the same direction, this can result in spreading out the vias, which can be useful for designing a redistribution layer (RDL) or other complex metallization stack.

In the following, some further embodiments are described.

In a nonlimiting illustrative embodiment, a method of via formation includes: forming a dielectric layer over a substrate; forming a resist layer over the dielectric layer; pressing a patterned mask to the resist layer to transfer a pattern of the patterned mask to the resist layer; curing the patterned resist layer; removing the patterned mask; etching via openings in the dielectric layer based on the patterned resist layer; and filling the via openings with an electrically conductive material to form vias.

In a nonlimiting illustrative embodiment, a method of via formation includes: forming a resist layer over a dielectric layer; imprinting a pattern of via openings in the resist layer; after the imprinting, transferring the pattern of via openings imprinted in the resist layer to the dielectric layer by anisotropic etching to form via openings in the dielectric layer; and filling the via openings in the dielectric layer with an electrically conductive material to form vias in the dielectric layer.

In a nonlimiting illustrative embodiment, an electrical connection structure includes: a first patterned metal layer; a dielectric layer disposed on the first patterned metal layer; a second patterned metal layer disposed on the dielectric layer, the dielectric layer being disposed between the first patterned metal layer and the second patterned metal layer; and vias passing through the dielectric layer and connecting the first patterned metal layer and the second patterned metal layer. A center line of at least one retargeting via of the vias is not parallel with a center line of at least one other via of the vias.

In a nonlimiting illustrative embodiment, a nano imprint lithography (NIL) mask includes a mask substrate and a patterned layer disposed on the mask substrate. The patterned layer includes at least one protrusion with a slanted sidewall corresponding to a via opening with a corresponding slanted sidewall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of via formation, the method comprising:
forming a dielectric layer over a substrate;
forming a resist layer over the dielectric layer;
pressing a patterned mask to the resist layer to transfer a pattern of the patterned mask to the resist layer;
curing the patterned resist layer;
removing the patterned mask;
etching via openings in the dielectric layer based on the patterned resist layer; and
filling the via openings with an electrically conductive material to form vias.

2. The method of claim 1, wherein the pattern of the patterned mask includes at least one slanted surface, and the etching transfers the slanted surface to the dielectric layer.

3. The method of claim 1, wherein:
center lines of the via openings are not mutually parallel; and
center lines of the vias are not mutually parallel.

4. The method of claim 1, wherein:
the dielectric layer has an upper surface distal from the substrate;
at least one noncircular via opening of the via openings has an upper aperture at the upper surface of the dielectric layer that is noncircular; and
the vias include at least one noncircular via formed by the filling of a corresponding noncircular via opening with the electrically conductive material.

5. The method of claim 1, wherein:
the dielectric layer has an upper surface distal from the substrate and a lower surface proximal to the substrate;
the via openings include at least one retargeted via opening, each retargeted via opening having a lower aperture at the lower surface of the dielectric layer and an upper aperture at the upper surface of the dielectric layer that is laterally offset from the lower aperture; and
the vias include at least one retargeted via formed by the filling of a corresponding retargeted via opening with the electrically conductive material.

6. The method of claim 1, wherein the substrate includes a first patterned metal layer, and the method further comprises, after forming the dielectric layer and before forming the resist layer:
forming a first resist layer over the dielectric layer; and
patterning the first resist layer to remove a portion of the first resist layer in a second patterned metal area;
wherein the filling of the via openings with the electrically conductive material to form the vias also fills the second patterned metal area with the electrically conductive material to form a second patterned metal layer, and the vias electrically connect the first patterned metal layer and the second patterned metal layer.

7. The method of claim 1, wherein the etching comprises plasma etching with low selectivity between material of the resist layer and material of the dielectric layer.

8. The method of claim 1, further comprising:
after filling the via openings with the electrically conductive material, removing excess electrically conductive material by performing chemical-mechanical polishing.

9. A method of via formation, the method comprising:
forming a resist layer over a dielectric layer;
imprinting a pattern of via openings in the resist layer;
after the imprinting, transferring the pattern of via openings imprinted in the resist layer to the dielectric layer by anisotropic etching to form via openings in the dielectric layer; and
filling the via openings in the dielectric layer with an electrically conductive material to form vias in the dielectric layer.

10. The method of claim 9, wherein the wherein the imprinting is performed using nano imprint lithography (NIL).

11. The method of claim 9, wherein the anisotropic etching has low etching selectivity between the resist layer and the dielectric layer.

12. The method of claim 9, wherein:
at least one noncircular via opening of the via openings has an aperture at a surface of the dielectric layer that is noncircular; and
the vias include at least one noncircular via formed by the filling of a corresponding noncircular via opening with the electrically conductive material.

13. The method of claim 9, wherein the dielectric layer has an upper surface and a lower surface, and wherein:
the via openings include at least one retargeted via opening, each retargeted via opening having a lower aperture at the lower surface of the dielectric layer and an upper aperture at the upper surface of the dielectric layer that is laterally offset from the lower aperture; and
the vias include at least one retargeted via formed by the filling of a corresponding retargeted via opening with the electrically conductive material.

14. The method of claim 9, wherein the dielectric layer is disposed on a substrate that includes a first patterned metal layer, and the method further comprises, before forming the resist layer:
forming a first resist layer over the dielectric layer; and
patterning the first resist layer to remove a portion of the first resist layer in a second patterned metal area;
wherein the filling of the via openings with the electrically conductive material to form the vias also fills the second patterned metal area with the electrically conductive material to form a second patterned metal layer, and the vias electrically connect the first patterned metal layer and the second patterned metal layer.

15. The method of claim 9, further comprising:
after filling the via openings with the electrically conductive material, removing excess electrically conductive material by performing chemical-mechanical polishing.

16. An electrical connection structure comprising:
a first patterned metal layer;
a dielectric layer disposed on the first patterned metal layer;
a second patterned metal layer disposed on the dielectric layer, the dielectric layer being disposed between the first patterned metal layer and the second patterned metal layer; and
vias passing through the dielectric layer and connecting the first patterned metal layer and the second patterned metal layer;
wherein a center line of at least one retargeting via of the vias is not parallel with a center line of at least one other via of the vias.

17. The electrical connection structure of claim 16, wherein the at least one retargeting via includes at least one via having a noncircular cross-section at its intersection with the second patterned metal layer.

18. The electrical connection structure of claim 16, wherein the at least one retargeting via includes at least one via having a circular cross-section at its intersection with the first patterned metal layer and a noncircular cross-section at its intersection with the second patterned metal layer.

19. The electrical connection structure of claim 16, wherein the at least one retargeting via includes at least one via having its intersection with the second patterned metal layer laterally offset from its intersection with the first patterned metal layer.

20. The electrical connection structure of claim 16, wherein the at least one retargeting via includes at least one via having a central axis that is not perpendicular to a surface of the dielectric layer on which the second patterned metal layer is disposed.
